(19) United States
(12) Patent Application Publication
(10) Pub. No.: US 2013/0305989 A1
(43) Pub. Date: Nov. 21, 2013

(54) METHOD AND APPARATUS FOR CLEANING RESIDUE FROM AN ION SOURCE COMPONENT

(71) Applicant: Axcelis Technologies, Inc., Beverly, MA (US)

(72) Inventors: Aseem K. Srivastava, Andover, MA (US); William F. DiVergilio, Cambridge, MA (US); Glen R. Gilchrist, Danvers, MA (US)

(73) Assignee: Axcelis Technologies, Inc., Beverly, MA (US)

(21) Appl. No.: 13/948,280

(22) Filed: Jul. 23, 2013

Related U.S. Application Data
(62) Division of application No. 12/616,662, filed on Nov. 11, 2009.

(51) Int. Cl. C23C 14/48

(52) U.S. Cl. CPC C23C 14/48
USPC 118/723 R

(57) ABSTRACT

Some techniques disclosed herein facilitate cleaning residue from a molecular beam component. For example, in an exemplary method, a molecular beam is provided along a beam path, causing residue build up on the molecular beam component. To reduce the residue, the molecular beam component is exposed to a hydro-fluorocarbon plasma. Exposure to the hydro-fluorocarbon plasma is ended based on whether a first predetermined condition is met, the first predetermined condition indicative of an extent of removal of the residue. Other methods and systems are also disclosed.

### REFERENCE TO RELATED APPLICATION

This application is a divisional of U.S. application Ser. No. 12/616,662 filed on Nov. 11, 2009.

### FIELD OF DISCLOSURE

The present invention relates generally to ion implantation systems, and more specifically to improved systems and methods for reducing residue buildup in such ion implantation systems.

### BACKGROUND

In the manufacture of semiconductor devices and other products, ion implantation systems are used to implant dopant elements into work pieces (e.g., semiconductor wafers, display panels, glass substrates). These ion implantation systems are typically referred to as “ion implanters”.

Ion dose and ion energy are two variables commonly used to characterize an ion implantation carried out by an ion implanter. The ion dose is associated with the quantity of ions implanted into a region of a work piece, and is usually expressed as a number of dopant atoms per unit area of work piece material (e.g., 10¹⁸ boron atoms/cm²). Ion energy is associated with a depth at which the ions are implanted beneath a surface of a work piece. For example, formation of relatively-deep junctions for retrograde wells in semiconductor devices typically requires ion energies of up to a few million electron volts (MeV), while formation of relatively-shallow junctions may demand energies below 1 thousand electron volts (1 keV).

Historically, many ion implantations have been carried out using small molecules or so-called “monatomic species”. However, in recent years, substantial improvements in throughput have been demonstrated by using large molecules, such as molecular boron (e.g., decaborane (B₁₀H₁₄), octadecaborane (B₁₈H₂₂)) or molecular carbon (e.g., C₇H₇, C₁₆H₁₄), for example. The use of large molecules provides significant advantages from a throughput perspective, because it allows each wafer to receive a given dose in a shorter time (relative to beams generated from monatomic species).

However, one potential drawback of using these large molecules is that they tend to dissociate after being ionized. This dissociation causes at least some dissociated molecules to “stick” to the inside of the ion implanter (e.g., ion source), causing residue buildup. After some time (e.g., 10-20 hours), the residue can impede operation of the ion source and reduce beam current.

Existing ion implanters attempt to remove the residue by purely physical means or by generating a plasma using NF₃ gas. However, both of these previous approaches have significant drawbacks. For example, purely physical means, such as bead blasting, typically requires a residue-coated component to be removed from the ion implantation apparatus in order for the component to be cleaned, which leads to machine downtime and potentially lost throughput for the fabrication facility. The use of plasma based on NF₃ gas is expensive because NF₃ requires special handling. In addition, in spite of the expense, NF₃ is still unable to remove several types of residues (e.g., graphitic residues due to plasma sources using carbon) and is unfriendly to the environment in many respects.

Accordingly, a need exists for a method of cleaning residue from the ion source in order to meet the needs of the ion implantation industry.

### SUMMARY

The following presents a simplified summary of the invention in order to provide a basic understanding of some aspects of the invention. This summary is not an extensive overview of the invention, and is neither intended to identify key or critical elements of the invention nor to delineate the scope of the invention. Rather, the purpose of the summary is to present some concepts of the invention in a simplified form as a prelude to the more detailed description that is presented later.

Some techniques disclosed herein facilitate cleaning of residue from a molecular beam component. For example, in an exemplary method, a molecular beam is provided along a beam path, causing residue build up on the molecular beam component. To reduce the residue, the molecular beam component is exposed to a plasma comprising fluorine. In some methods, different kinds of plasma can be selectively generated to clean different kinds of residue on the molecular beam component.

In an exemplary system, a reactive gas delivery system includes a flow controller that supplies various types of gas to one or more plasma chambers. The flow controller selectively delivers some of the gases, such as boron compounds and carbon compounds, to generate plasma discharges that are subsequently used to achieve ion implantation into one or more work pieces. The boron and/or carbon compounds can cause different types of residues to buildup in the system. Accordingly, the flow controller also can selectively deliver different types of cleaning gases to one or more plasma chambers to generate different plasma discharges to selectively remove the different types of residue from the system.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is an embodiment of an ion implantation system.

FIG. 2 is an embodiment of an ion implantation system that includes a reactive gas delivery system in accordance with some embodiments.

FIG. 3 is a flow chart of a method for limiting or cleaning residue buildup from an ion implanter component according to an embodiment.

FIG. 4 is a flow chart of another method for limiting or cleaning residue buildup from an ion implanter component according to an embodiment.

FIG. 5 illustrates an isometric perspective view of an exemplary ion source to generate the molecular beam in accordance with one embodiment.

FIG. 6 illustrates a cross sectional perspective view of an exemplary ion source to generate the molecular beam in accordance with one embodiment.

FIG. 7 illustrates one mechanism of generating a cleaning plasma in close proximity to the ion source components that are susceptible to residue buildup.

### DETAILED DESCRIPTION

The present invention is directed generally towards residue removal techniques that are applicable to ion implantation systems. More particularly, the system and methods of the present invention provide an efficient way to reduce residue generated by large molecular species, such as, for example: carborane; decaborane; octadecaborane and icosaboranes; hydrocarbons such as C₇H₇ and C₁₀H₁₄, as well as standard ionization gases for the production of small molecular ion implant species (e.g., BF₂, and monatomic species), such as boron trifluoride, phosphine and arsine. It will be understood that the foregoing list of ion implantation species is provided for illustrative purposes only, and shall not be considered to represent a complete list of the ionization gases that could be used to generate ion implant species. Accordingly, aspects of the present invention will now be described with reference to the drawings, wherein like reference numerals are used to refer to like elements throughout.

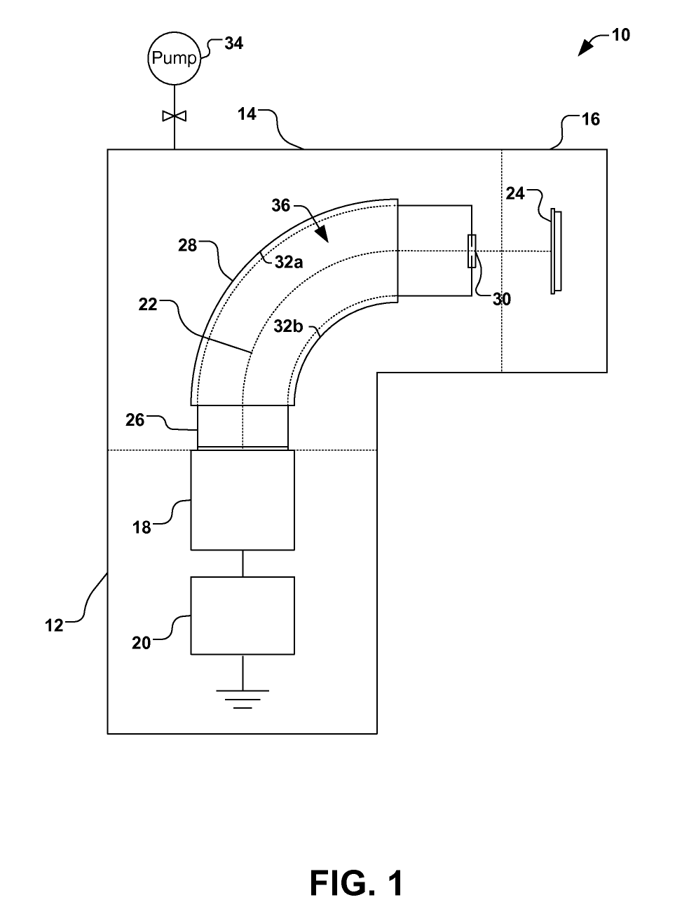

FIG. 1 illustrates an ion implantation system 10 having a terminal 12, a beamline assembly 14, and an end station 16. Generally speaking, an ion source 18 in the terminal 12 is coupled to a power system 20 to ionize a dopant gas and form an ion beam 22 using small molecules (such as BF₂, and monatomic species) or large molecules. The beam 22 is passed through the beamline assembly 14 before bombarding a work piece 24 (e.g., a semiconductor wafer, or a display panel) located in the end station 16.

To steer the beam 22 from the terminal 12 to the work piece 24, the beamline assembly 14 has a beamguide 26 and a mass analyzer 28. A dipole magnetic field is established in the mass analyzer 28 during operation. Ions having an inappropriate charge-to-mass ratio collide with the sidewalls 32a, 32b; thereby leaving only the ions having the appropriate charge-to-mass ratio to pass through a resolving aperture 30 and into the work piece 24. The beam line assembly 14 may also include various beam forming and shaping structures extending between the ion source 18 and the end station 16, which maintain the ion beam 22 and bound an elongated interior cavity or passageway 36 through which the beam 22 is transported to the work piece 24 supported in the end station 16. A vacuum pump 34 typically keeps the ion beam transport passageway 36 at vacuum to reduce the probability of ions being deflected from the beam path through collisions with air molecules.

The implanter 10 may employ different types of end stations 16. For example, “batch” type end stations can simultaneously support multiple work pieces 24 on a rotating support structure, wherein the work pieces 24 are rotated through the path of the ion beam until all the work pieces 24 are completely implanted. A “serial” type end station, on the other hand, supports a single work piece 24 along the beam path for implantation, wherein multiple work pieces 24 are implanted one at a time in serial fashion, with each work piece 24 being completely implanted before implantation of the next work piece 24 begins.

Absent countermeasures, various contaminants (e.g., boron, carbon, or other dopant material from the ion source 18) can deposit and form one or more types of residue on various ion implanter components adjacent to the beam 22. For example, when boron species are present in the beam 22, boron-based residue can build up in an ion source; while when carbon species are present in the beam 22 carbon-based residue can similarly build up. Other types of residue can also build up depending on the types of implantation carried out. Aspects of this disclosure relate to techniques for removing or otherwise limiting such residue.

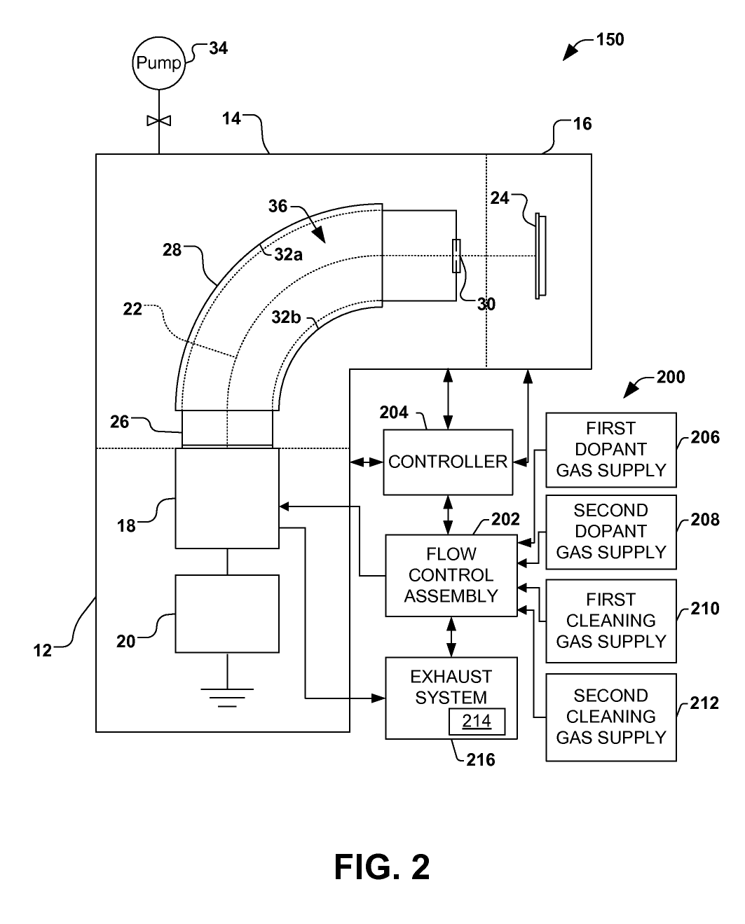

FIG. 2 illustrates an example of an ion implantation system 150 that tends to limit build-up of residue, thereby helping to ensure reliable operation of the system over a long period of time. In addition to the components previously discussed, FIG. 2's ion implantation system 150 includes a reactive gas delivery system 200. The reactive gas delivery system 200 includes a flow control assembly 202 that typically comprises mechanical and/or electro-mechanical components (e.g., valves, pumps and flow tubes) to deliver various gases to the ion implantation system 150 under the direction of a controller 204. In particular, the various gases can be selectively delivered to generate different plasma discharges that are adapted to remove different types of residue that may build up on ion system components. In some embodiments, rather than the plasma actually cleaning the residue, an afterglow of the plasma can actually clean the residue. As appreciated by one of ordinary skill in the art, the term “plasma” is used for an active generation region where RF, or microwaves actually impinge and create the plasma (consisting of ions, electrons, metastables, neutrals, etc.), whereas afterglow is a downstream region where the species are no longer created, but are forced due to diffusion and are effectively utilized.

In the illustrated embodiment, the flow control assembly 202 is shown coupled to first and second dopant gas supplies (206, 208), as well as first and second cleaning gas supplies (210, 212). Often, the gas supplies 206-212 are stored in gas canisters, although the desired gases can also be generated in situ by carrying out appropriate chemical reactions and/or ionizations. It will be appreciated that although the illustrated embodiment depicts only first and second dopant gas supplies (206, 208) and first and second cleaning gas supplies (210, 212), any number of such gas supplies may be included to carry out desired implantation and cleaning functionality.

During operation, the controller 204 instructs the flow control assembly 202 to supply dopant gases from the dopant gas supplies 206, 208 to a plasma chamber (not shown) in the ion source 18, which is in a vacuum state. The power system 20 is then energized to ionize the dopant gas molecules in the plasma chamber, thereby generating different types of plasma depending on which dopant gas is present in the plasma chamber. For example, in one embodiment, the first dopant gas supply 206 comprises molecular boron (e.g., decaborane (B₁₀H₁₄), octadecaborane (B₁₈H₂₂)) and the second dopant gas supply 208 comprises molecular carbon (e.g., C₇H₇, C₁₆H₁₄). During implantation of a first workpiece (or one or more batches of workpieces), the molecular boron can be supplied to the plasma chamber to generate a first plasma, which can be extracted to form a first type of ion beam 22 that is suitable for forming an n-type region on the work piece(s). When another workpiece (or another batch of workpieces) is to be subsequently implanted, the molecular carbon can be supplied to the plasma chamber to generate a second plasma, which can be extracted to form a second type of ion beam 22 that is suitable for forming compressive strain regions in semiconductor devices.

Because the first and second types of ion beams include different molecular species, the first and second ion beams can form different kinds of residue in the system. Unless appropriate measures are taken, these different kinds of residue can buildup to push beam current beneath desired levels. Based on whether residue is present (and/or based on whether a predetermined time between cleaning routines has occurred), the controller 204 can initiate a cleaning process to reduce any such residue.

If a first type of residue, such as boron-based residue, is present (and/or if a pre-determined time has elapsed from a previous cleaning operation), the controller 204 instructs the flow control assembly 202 to pump the plasma chamber down to vacuum and then supply a first cleaning gas from the first cleaning gas supply 210 to a second plasma source that is used exclusively for cleaning purposes. For example, in some embodiments, the first cleaning gas comprises a fluorocarbon (having molecular formula CₐF_{b}, where a and b are integers) and/or a hydro-fluorocarbon (having molecular formula CₓF_{y}H_{z}, where x, y, and z are integers). When this first cleaning gas is ionized and plasma is generated therefrom, its free reactive fluorine atoms can remove the first type of residue (e.g., boron-based residue). In some embodiments, the first cleaning gas may be substantially, if not completely, free of NF₃ gas; thereby alleviating the need for special gas handling techniques, reducing costs, and tending to make the inventive techniques more environmentally friendly in some respects than NF₃-based cleaning techniques.

Conversely, if a second type of residue, such as carbon based residue is present (and/or if a pre-determined time has elapsed from a previous cleaning operation), the controller 204 can also instruct the flow control assembly 202 to pump the plasma chamber down to vacuum, and then supply a second cleaning gas from the second cleaning gas supply 212 to the second plasma source. The second cleaning gas may comprise oxygen, thereby generating a plasma comprising atomic oxygen that removes the second type of residue (e.g., carbon-based residue) from an ion source component. Like the first cleaning gas, the second cleaning gas may also be substantially, if not completely, free of NF₃ gas.

By changing between different types of plasma discharges to selectively clean different types of residues, this disclosure facilitates reliable operation for the ion implantation system. Although this concept is discussed above with respect to only first and second cleaning plasma discharges to clean first and second types of residue, respectively, this concept is extendable to any number of cleaning plasma discharges operable to clean any number of types of residue, respectively.

To help determine whether one or more residues have been completely cleaned from the ion source components, the system may employ various residue detection systems. For example, FIG. 2 depicts a residue detection sensor 214 located in an exhaust system 216 in fluid communication with the plasma chamber in the ion source 18. Although FIG. 2 depicts an embodiment where the residue detection sensor 214 resides in the exhaust system 216, in other embodiments the residue detection sensor could be located in other regions. For example, a residue detection sensor 214 could also be located downstream of the ion source, such as in the beamline assembly 14, for example.

In one embodiment, the residue detection sensor 214 can enable optical spectroscopic analysis that makes use of a secondary plasma source (not shown) in the exhaust system 216. Accordingly, in this embodiment, the residue detection sensor 214 analyzes exhaust from the plasma chamber in the ion source for trace amounts of residue. When plasma is ignited in the secondary plasma source, residue (if present) emits photons/light at a predetermined quantized energy level indicative of residue. The light emitted from different types of residue serve as a kind of “fingerprint” by which different types of residue can be identified, thereby allowing the controller 204 to select an appropriate cleaning gas to remove the particular type of residue detected. Alternately, as the built up residue gets cleaned up, less and less residue flows into the exhaust system and once all the residue is gone the optical fingerprint drops below a certain preset threshold, which can allow the controller 204 to terminate the cleaning process, thereby providing real-time control of the length of cleaning required.

In another embodiment, the residue detection sensor 214 can enable residual mass analysis that makes use of a secondary plasma source and a quadrupole magnet (not shown) located in the exhaust system 216. In residual gas analysis (RGA), the molecular constituents of the exhaust are again analyzed for trace amounts of residue, but this time based on the respective atomic masses of the molecular constituents. Thus, in this embodiment, the masses that are detected serve as a kind of “fingerprint” by which different types of residue can be identified, thereby allowing the controller 204 to select an appropriate cleaning gas to remove the particular type of residue detected.

In still another embodiment, the residue detection sensor 214 can comprise a temperature sensor. When a residue molecule disassociates in the presence of reactive species, the chemical reactions are typically exothermic, which tend to heat up the surfaces upon which the residue had formed according to a characteristic temperature curve, which can be indicative of whether residue is being removed. Once the temperature sensor typically mounted to the ion source components shows no further rise in temperature, the exothermic chemical reactions between the residue and reactive cleaning plasma are complete, and the temperature sensor's data may be used to stop the cleaning process.

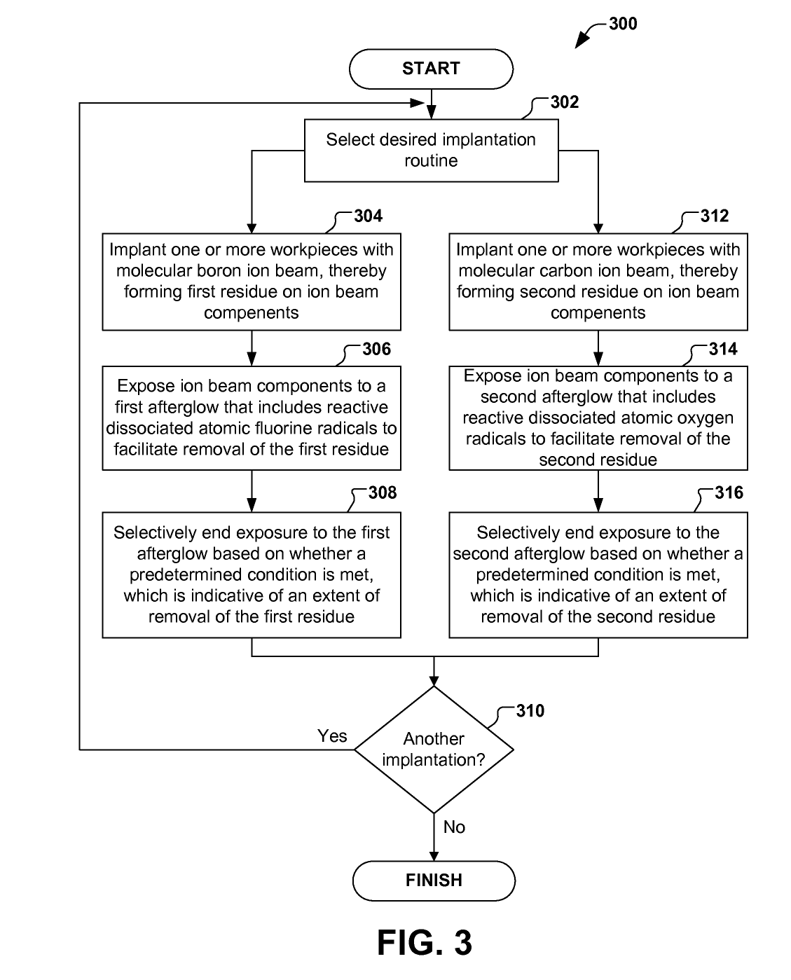

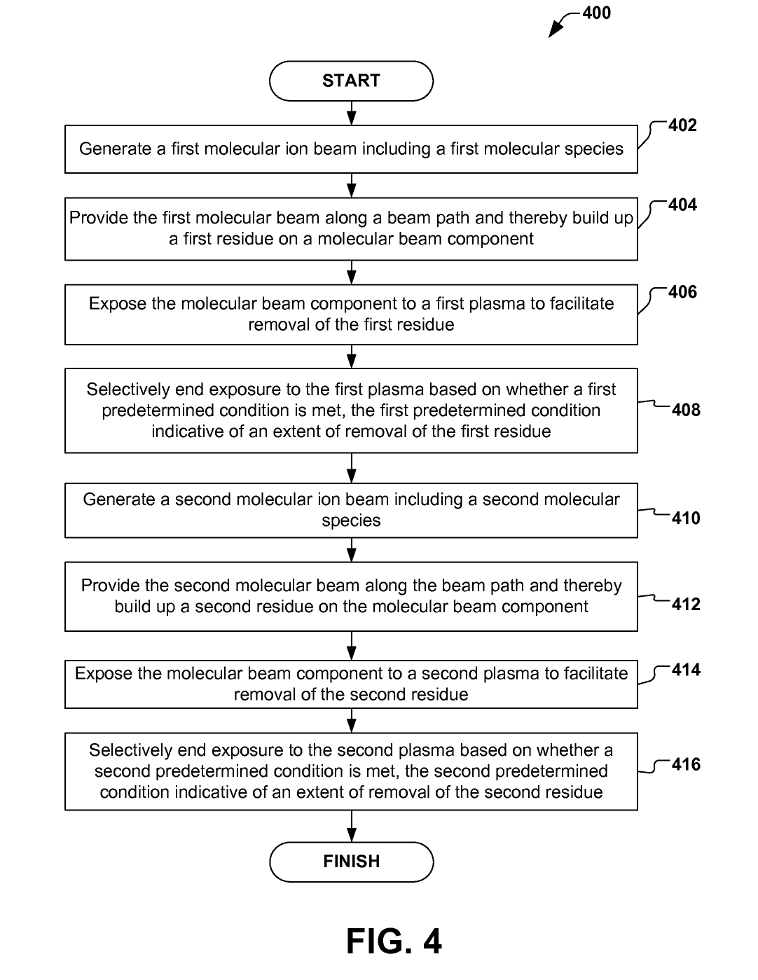

Now that some examples of ion implantations systems have been discussed, reference is made to FIGS. 3-4, which show methods 300, 400 in accordance with some aspects. While these methods are illustrated and described below as a series of acts or events, the present disclosure is not limited by the illustrated ordering of such acts or events. For example, some acts may occur in different orders and/or concurrently with other acts or events apart from those illustrated and/or described herein. In addition, not all illustrated acts are required, and one or more of the acts depicted herein may be carried out in one or more separate acts or phases.

FIG. 3 illustrates a method 300 that begins at 302 when a desired implantation routine is selected. For example, the desired implantation routine may deliver a desired n-type doping profile, a desired p-type doping profile, or some other type of implant, such as a carbon implant, for example.

If a first type of implantation routine is selected, the method proceeds to 304 and one or more workpieces are implanted with a molecular boron ion beam. This implantation may cause a first type of residue to build up on one or more ion beam components.

At 306, the molecular beam component having the first type of residue thereon is exposed to a first afterglow (or a first cleaning plasma), which comprises reactive dissociated atomic fluorine radicals to facilitate removal of the residue. In some examples, the first cleaning plasma which gives rise to the first afterglow may be generated by using a gas mixture that comprises a fluorocarbon and/or hydro-fluorocarbon gas.

At 308, exposure to the first afterglow (or first cleaning plasma) is selectively ended based on whether a first predetermined condition is met. The first predetermined condition is indicative of an extent of removal of the residue. For example, in one embodiment, the first condition relates to whether a predetermined time has expired as measured from a starting time of the exposure to the first afterglow. In another embodiment, the first condition relates to whether optical spectroscopic analysis using a secondary plasma source located preferably, though not limited to, in the exhaust line indicates whether the first afterglow has completely removed the residue from the ion source component. In still another embodiment, the first condition relates to whether a residual gas mass analysis indicates whether the first afterglow has completely removed the residue from the ion source component. In still another embodiment, the first condition relates to whether a temperature measurement indicates whether the first afterglow has completely removed the residue from the ion source component. Note that the first condition could also relate to less than a complete removal of the residue in these and other embodiments.

At 310, the method determines if another implantation is required. If so, the method returns to 302 and selects another implantation routine to be carried out on the same or different workpiece as previously implanted.

Assuming a second implantation routine is selected at 302, at 312 one or more workpieces are implanted with a molecular carbon beam. This forms a second residue on the ion beam component.

At 314, the ion beam component is exposed to a second afterglow (or a second cleaning plasma) comprising reactive dissociated atomic oxygen radicals to facilitate removal of the second residue formed, for example, during the molecular carbon implant.

At 316, exposure to the second afterglow (or second cleaning plasma) is selectively ended based on whether a second predetermined condition is met, where the second predetermined condition is indicative of an extent of removal of the second residue. For example, in one embodiment, the second condition relates to whether a predetermined time has expired as measured from a starting time of the exposure to the second afterglow. In another embodiment, the second condition relates to whether optical spectroscopic analysis using a secondary plasma source indicates whether the second afterglow has completely removed the residue from the ion source component. In still another embodiment, the second condition relates to whether a residual gas mass analysis indicates whether the second afterglow has completely removed the residue from the ion source component. In still another embodiment, the second condition relates to whether a temperature measurement indicates whether the second afterglow has completely removed the residue from the ion source component. Note that the second condition could also relate to less than a complete removal of the residue in these and other embodiments.

Although not explicitly shown in FIG. 3, other exposures to additional different kinds of afterglow or cleaning plasma can be carried out to further remove any residue that remains on the ion source component. Each exposure can be tailored to remove a different type of residue from the ion source component, thereby reducing residue buildup so reliable implant operation can be achieved.

FIG. 4 shows another method 400 in accordance with some embodiments. The method 400 starts at 402 when a first molecular beam is generated, where the first molecular beam includes a first molecular species. For purposes of illustration, the remaining acts of method 400 are described below with respect to an implementation where the first molecular species is boron, but other molecular species could also be used.

At 404, the first molecular beam is provided along a beam path, which causes a first residue to buildup on molecular beam components.

At 406, the molecular beam components are exposed to a first cleaning plasma to facilitate removal of the first residue. In the example implementation now described, the first cleaning plasma includes fluorine ions and/or fluorine radicals, such as can be generated from fluorocarbons or hydro-fluorocarbons, for example.

At 408, exposure to the first cleaning plasma is selectively ended based on whether a first predetermined condition is met. For example, the first condition can relate to time, a spectrographic optical analysis, a residual gas mass analysis, or a temperature analysis.

At 410, a second molecular ion beam is generated, which includes a second molecular species. In the example now described, the second molecular species is described as carbon, which is one non-limiting example.

At 412, the second molecular ion beam is provided along the beam path, causing a second residue to buildup on the molecular beam component.

At 414, the molecular beam component is selectively exposed to a second cleaning plasma that differs from the first cleaning plasma to facilitate removal of the second residue. In the example now described, the second cleaning plasma includes oxygen, which is one non-limiting example.

At 416, exposure to the second cleaning plasma is selectively ended based on whether a second predetermined condition is met. For example, the second condition can relate to time, a spectrographic optical analysis, a residual gas mass analysis, or a temperature analysis.

Although not explicitly shown in FIG. 4, other types of ion beams can be generated, creating other types of residue buildup. In addition, exposures to other, different kinds of plasma can be carried out to further remove any residue formed on the ion source component. In some embodiments, each exposure can be tailored to remove a different type of residue from the ion source component, thereby reducing residue buildup so reliable operation can be achieved.

Often, the method illustrated in FIG. 4 is carried out after a batch (or multiple batches) of wafers has been implanted with the first and/or second species, as long as beam current can be maintained. In some embodiments, both the first and second cleaning processes (for first species as well as second species) may be employed in a serial manner at a predetermined maintenance schedule (e.g., once a set number of wafers have been implanted). It is possible that the cleaning processes may be alternately carried out several times to ensure any residue is removed in a desired manner.

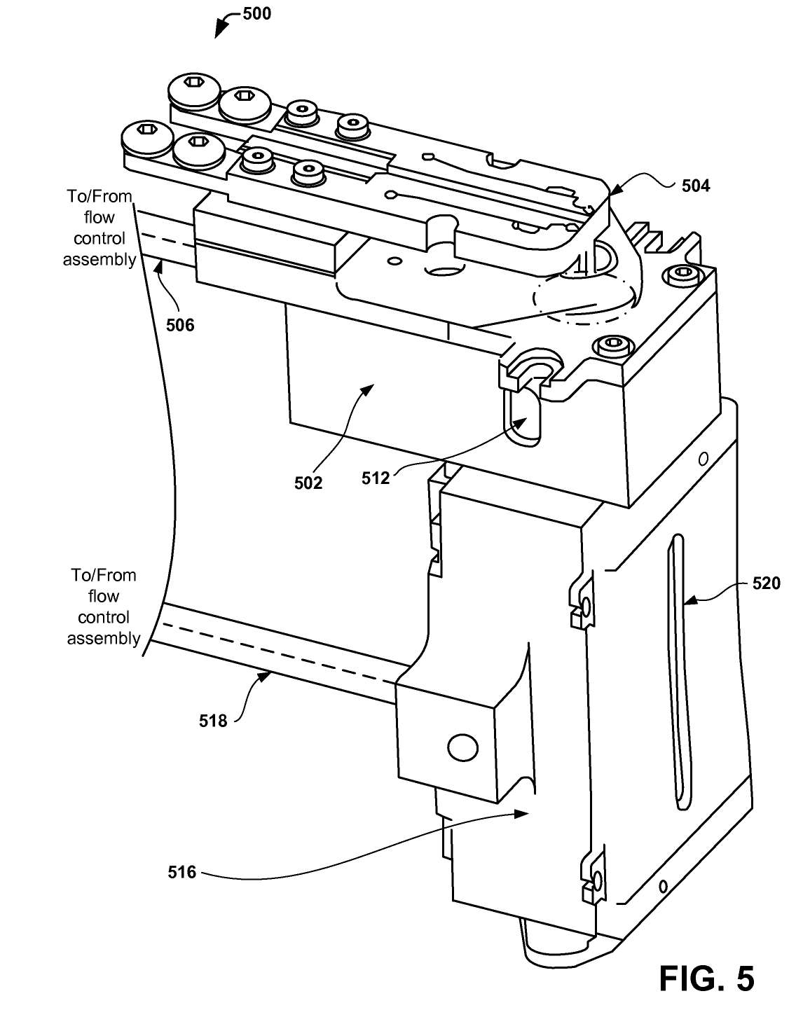

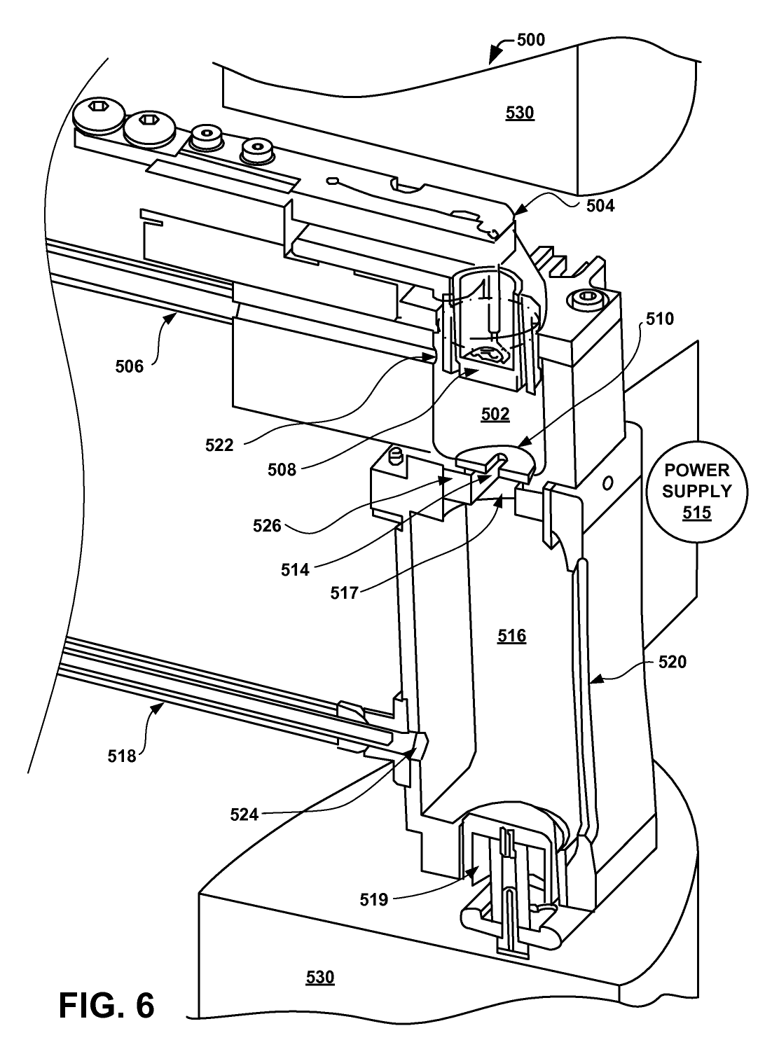

FIGS. 5-6 show an embodiment of an ion source 500 that can be used in accordance with some embodiments. It should be noted that the ion source 500 depicted in FIGS. 5-6 is provided for illustrative purposes as merely one type of ion source that is susceptible to residue buildup (e.g., on aperture 520) and is not intended to include all aspects, components, and features of an ion source. Instead, the exemplary ion source 500 is depicted so as to facilitate a further understanding of one type of ion source that could be used in conjunction with some embodiments.

The ion source 500 comprises a first plasma chamber 502 situated adjacent a second plasma chamber 516. The first plasma chamber 502 includes a gas source supply line 506 and is a configured with a plasma generating component 504 for creating plasma from a first source gas. The gas supply line selectively carries a dopant gas (e.g., from the first and/or second dopant gas supply 206, 208 of FIG. 2). Plasma from the secondary cleaning-plasma-source (e.g., which uses gas supplied from the first and/or second cleaning gas supply 210, 212 of FIG. 2) is carried to the first plasma chamber 502 through gas/afterglow line 518.

The plasma generating component 504 can comprise a cathode 508/anode 510 combination, as shown in FIG. 6. Alternatively, the plasma generating component 504 may include an RF induction coil antenna that is supported having a radio frequency conducting segment mounted directly within a gas confinement chamber to deliver ionizing energy into the gas ionization zone.

The first, or electron source, plasma chamber 502 defines an aperture 512 forming a passageway into a high vacuum region of an ion implantation system, i.e. a region wherein pressure is much lower than the pressure of the source gas in the first plasma chamber 502.

The electron source plasma chamber 502 also defines an aperture 514 forming an extraction aperture for extracting electrons from the electron source plasma chamber 502. In a preferred embodiment, the extraction aperture 514 is provided in the form of a replaceable anode element 510 as illustrated in FIG. 6, having an aperture 514 formed therein. As such, it will be recognized by those of skill in the art that the electron source plasma chamber 502 can be configured to have a positively biased electrode 519 (relative to the cathode 508) for attracting electrons from the plasma in a so-called non-reflex mode. Alternatively, the electrode 519 can be biased negatively relative to the cathode 508 to cause electrons to be repelled back into the electron source plasma chamber 502 in a so-called reflex mode. It will be understood that this reflex mode configuration would require proper biasing of the plasma chamber walls, together with electrical insulation and independent biasing of the electrode 519.

As previously stated, the ion source 500 also includes a second, or ion source chamber 516. The second ion source plasma chamber 516 includes a second gas source supply line 518 for introducing a source gas into the ion source plasma chamber 516 and is further configured to receive electrons from the electron source plasma chamber 502, thereby creating plasma therein via the collisions between the electrons and the second source gas. The second gas supply source line 518 can selectively carry a dopant gas (e.g., from the first and/or second dopant gas supply 206, 208 of FIG. 2) and/or a cleaning plasma from the secondary cleaning-plasma source (e.g., that uses gas from the first and/or second cleaning gas supply 210, 212 of FIG. 2) to the second plasma chamber 516.

The second, or ion source, plasma chamber 516 defines an aperture 517 aligned with the extraction aperture 514 of the first plasma chamber 502, forming a passageway therebetween for permitting electrons extracted from the first plasma chamber 502 to flow into the second plasma chamber 516. Preferably, the ion source plasma chamber 516 is configured to have a positively biased electrode 519 for attracting electrons injected into the ion source plasma chamber 516 in a so-called non-reflex mode to create the desired collisions between electrons and gas molecules to create ionization plasma. Alternatively, the electrode 519 can be biased negatively to cause electrons to be repelled back into the ion source plasma chamber 516 in a so-called reflex mode.

An extraction aperture 520 is configured in the second plasma chamber 516 to extract ions for formation of an ion beam for implantation.

In one embodiment the second plasma chamber 516 is biased positively with respect to the first plasma chamber 502 utilizing an external bias power supply 515 (FIG. 6). Electrons are thus extracted from the electron source plasma chamber 502 and injected into the ion source plasma chamber 516 where collisions are induced in the second plasma chamber 516 between the electrons provided by the first plasma chamber 502 and the supply gas supplied to the second plasma chamber 516 via the second gas source supply line 518, to create a plasma.

It should be noted that the first plasma chamber 502 and the second plasma chamber 516 can have three open boundaries: a gas inlet (e.g., a first gas supply inlet 522 and a second gas supply inlet 524), an opening to a high vacuum area (e.g., pumping aperture 512 and extraction aperture 520) and a common boundary apertures 514 and 517 forming the common passageway between the first and second plasma chambers, 502 and 504, respectively.

Both plasma chambers 502, 516 also share a magnetic field oriented along the extraction aperture, provided by a standard Axcelis source magnet, depicted by reference numeral 530. It is well known that the ionization process (and in this case the electron generating process) becomes more efficient by inducing a vertical magnetic field in the plasma generating chamber. As such, in one embodiment electromagnet members 530 are positioned outside of the first and second plasma chambers, 502 and 516 respectively, preferably along the axis of the shared boundary therebetween. These electromagnet elements 530 induce a magnetic field that traps the electrons to improve the efficiency of the ionization process.

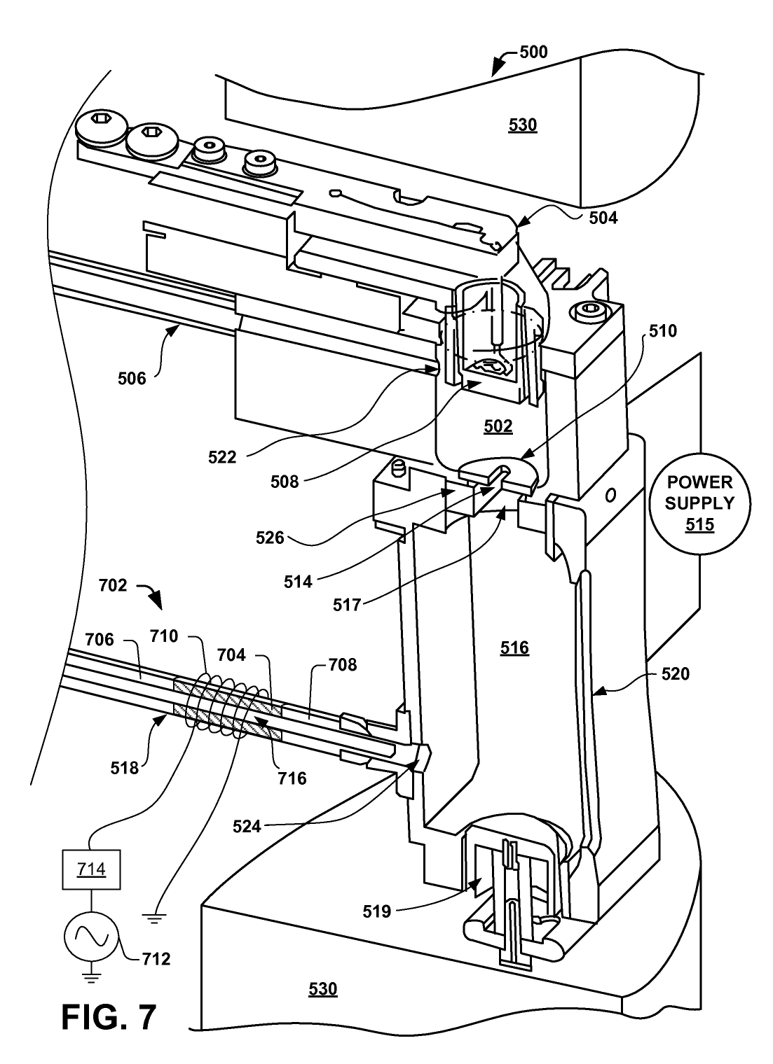

FIG. 7 show one embodiment where the cleaning plasma is actually generated in a secondary plasma source 702 positioned within the gas supply source line 518. In this embodiment, the reactive gases (e.g., supplied from the gas cleaning supplies 210, 212 in FIG. 2) are transported the length of gas supply source line 518 (e.g., approximately two meters). In this embodiment, the gas supply source line 518 comprises a dielectric conduit 704 coupled laterally between first and second conductive conduits 706, 708, respectively. The first conductive conduit 706 may be referred to as a gas supply line, whereas the second conductive conduit 708 may be referred to as an afterglow supply line. In some embodiments, the dielectric conduit 704 can comprise sapphire (for fluorine compatibility) and the conductive conduits 706, 708 can comprise metal. An inductive coil 710 is also wrapped around the gas supply source line 518 very near the aperture 524. When an RF power supply 712, which is coupled to the inductive coil 710 via a matching network 714, is activated, a highly concentrated plasma is generated in a region 716 in the gas supply source line 518. Thus, the plasma is generated very close to the first and/or second chamber 502, 516 where the reactive species are to be used to clean residue. Although FIG. 7 shows an embodiment that includes an RF coil 710, other embodiments can use with a microwave source or other plasma generating component that is close to the opening 524.

The configuration of FIG. 7 is advantageous over previous implementations where a secondary plasma source was located at a far end of the gas/afterglow source supply line 518. When a plasma was generated at the far end of the gas/afterglow source supply line 518 (e.g., often about 2 meters from the ion source), conductance and surface recombination losses on the walls of the gas/afterglow supply source line 518 cause the loss of a significant percentage of the reactive gas species generated in the plasma source. Therefore, by including a plasma generating component within the gas supply source line 518, FIG. 7's arrangement helps to ensure that more reactive gas molecules diffuse efficiently to the ion source and thereby help to facilitate effective cleaning of residue from components in the ion source. As a corollary, generating the cleaning plasma so close to the source components 516 and 502 may improve efficiency by not requiring large flow of cleaning gas, or by significantly reducing RF power usage.

Although the invention has been illustrated and described with respect to one or more implementations, alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. An ion implantation system, comprising:
an ion source configured to provide a molecular beam which travels along a beam path in the ion implantation system;
a flow control assembly in fluid connection with: at least one plasma chamber disposed on the beam path, a plurality of different dopant gas supplies, and a plurality of different cleaning gas supplies;
a controller adapted to instruct the flow control assembly to selectively deliver gas from the different dopant gas supplies to one or more of the at least one plasma chamber to facilitate extraction of different molecular beams having different respective species at different respective times along the beam path; and
the controller further adapted to selectively deliver gas from the different cleaning gas supplies to generate different types of plasma discharge in the one or more of the at least one plasma chamber, where the different types of plasma discharge are adapted to reduce buildup of different types of residue formed when the molecular beams having different species are extracted along the beam path.

2. The ion implantation system of claim 1, wherein the at least one plasma chamber comprises a first plasma chamber situated adjacent to a second plasma chamber in the ion source.

3. The ion implantation system of claim 2, further comprising:
a gas supply line adapted to selectively supply gas from one of the plurality of cleaning gas supplies towards the first plasma chamber; where the gas supply line comprises a dielectric conduit coupled between first and second conductive conduits and arranged to provide fluid communication therebetween; and
a plasma generation component adapted to generate a plasma within a cavity defined by an inner-surface of the dielectric conduit.

4. The ion implantation system of claim 3, wherein the plasma is generated so an afterglow of the plasma drifts or diffuses into at least one of the first or second plasma chamber to remove residue built up on an ion source component in the ion source.

5. The ion implantation system of claim 3, wherein the dielectric conduit comprises sapphire.

6. The ion implantation system of claim 3, wherein the plasma generation component comprises:
a radio-frequency (RF) coil that is wound around the dielectric conduit; and
an RF power supply to drive the RF coil.

7. The ion implantation system of claim 3, wherein the plasma generation component comprises a microwave source.

8. The ion implantation system of claim 1, wherein the ion source is configured to extract a first molecular beam along the beam path and concurrently build up a first residue on an ion source component, where the first molecular beam is generated by using a first dopant gas that includes a first molecular species; and
wherein the ion source is further configured to extract a second molecular beam along the beam path and concurrently build up a second residue on the ion source component, where the second molecular beam is generated by using a second dopant gas that includes a second molecular species and where the second residue differs in composition from the first residue.

9. The ion implantation system of claim 8, wherein the controller is configured to provide a first cleaning gas from the different cleaning gas supplies to generate a first type of plasma discharge in the one or more of the at least one plasma chamber at a first time, and to provide a second, different cleaning gas from the different cleaning gas supplies to generate a second type of plasma discharge in the one or more of the at least one plasma chamber at a second time that differs from the first time.

10. The ion implantation system of claim 9, wherein a removal of the first residue by the first plasma is non-concurrent with removal of the second residue by the second plasma.
